(19) United States
(12) Patent Application Publication
(10) Pub. No.: US 2010/0078067 A1
(43) Pub. Date: Apr. 1, 2010

(54) CARBON NANOTUBE FILM BASED SOLAR CELL AND FABRICATING METHOD THEREOF

(76) Inventors: Yi Jia, Beijing (CN); Jinquan Wei, Beijing (CN); Qinke Shu, Beijing (CN); Kunlin Wang, Beijing (CN); Daming Zhuang, Beijing (CN); Gong Zhang, Beijing (CN); Wenjin Liu, Beijing (CN); Jianbin Luo, Beijing (CN); Zhicheng Wang, Beijing (CN); Dehai Wu, Beijing (CN)

Correspondence Address: CONNOLLY BOVE LODGE & HUTZ, LLP, P O BOX 2207, WILMINGTON, DE, 19899, US

(21) Appl. No.: 12/521,691

(22) PCT Filed: Dec. 28, 2007
(86) PCT No.: PCT/CN2007/003863

§ 371 Date: Jul. 24, 2009

(30) Foreign Application Priority Data
Dec. 29, 2006 (CN) 200610169827.0

(51) Int. Cl. H01L 31/00; H01L 31/18

(52) U.S. Cl. 136/256; 136/261; 438/57; 977/742; 977/948; 257/E21.211

(57) ABSTRACT

A carbon nanotube-based solar cell and fabricating method thereof are provided. The method is achieved by applying carbon nanotube film (1) photoelectric conversion material and an upper electrode simultaneously. The method improves photoelectric conversion efficiency and life time of the solar cell, the fabricating method of the solar cell is simple, and the fabricating cost is low.

### TECHNICAL FIELD

The present invention relates to a solar cell and a process for manufacturing the same. More specifically, the present invention relates to a solar cell taking carbon nanotube film as a photoelectric conversion material, and also a process for manufacturing the same.

### BACKGROUND

Currently, solar energy is the cleanest energy source, which could almost be utilized endlessly. As far as we know, the solar energy received by globe per 40 seconds is equal to those contained in 21 billion barrels of petroleum, corresponding to the sum of those consumed a whole day on the earth. The utilization of solar energy includes the conversion of sunlight energy to heat, sunlight energy to electricity, and sunlight energy to chemical energy. Solar cell is a typical example for converting sunlight energy to electricity (which is also known as photoelectric conversion); and it is based on photovoltaic effect of semiconductor material. According to the types of the photoelectric conversion semiconductor materials, solar cells can be classified as silicon based solar cell, gallium arsenide based solar cell, copper-indium-gallium-selenium film solar cell, organic film solar cell, and etc. Currently, the majority (over 90%) of commercially available solar cell is based on silicon, and comprises monocrystalline silicon solar cell, polycrystalline silicon solar cell, amorphous silicon film solar cell, and polycrystalline silicon film solar cell. Theoretically, the conversion efficiency of monocrystalline silicon based solar cell is up to 26%. However, the practical conversion efficiency thereof is much lower than the theoretical value; actually, the conversion efficiency of the commercially available solar cell in China is usually lower than 15%.

In order to improve the conversion efficiency of silicon based solar cell, techniques, such as back surface field, shallow junction, texture surface, antireflection film and etc, have been adopted. By way of examples, in 1999, Green M. A., et al., University of New South Wales, Australia (Green M. A. et al., IEEE Trans. Electron Devices, 1999, 46: 1940-1947) prepared a passivated emitter monocrystalline silicon solar cell with a conversion efficiency of 24.7%, which was already very close to the theoretical upper limit of a silicon solar cell. The production cost of polycrystalline silicon based solar cell is lower than that of monocrystalline silicon solar cell, but the grain boundary thereof has certain negative influence on the conversion efficiency. In 1999, Zhao J. H. et al., University of New South Wales, Australia (Zhao J. H. et al., IEEE Trans. Electron Devices, 1999, 46: 1978-1983) prepared a passivated emitter polycrystalline silicon solar cell with an efficiency conversion of 19.8%. Since amorphous silicon has high absorption efficiency for sunlight, the amount of silicon material used may thus be reduced; a laboratory-prepared single junction, double junction and multijunction amorphous silicon solar cells exhibit conversion efficiencies of 6-8%, 10% and 13%, respectively (Zhao Yuwen, Physics, 2004, 33: 99-105). Polycrystalline silicon film solar cell has both the advantages of high conversion efficiency and stability of crystalline silicon solar cell, and the advantage of savings in material cost of film solar cell, the conversion efficiency of a laboratory sample may achieve up to 18%. Xu Ying et al., Beijing solar energy research institute (Xu Ying. et al., Acta Energiae Solaris Sinica, 2002, 23: 108-110) adopts rapid thermal chemical vapor deposition technique to prepare polycrystalline silicon film solar cell on a simulating non-silicon substrate, and he also prepares a anti-reflection film, the conversion efficiency of the solar cell is up to 10.21%.

However, the production of silicon based solar cell is complicated at present; since only silicon is used as the photoelectric conversion material of solar cell, in order to obtain high conversion efficiency, raw material silicon with very high purity has to be prepared. Currently, the production process for the raw material silicon is far below the demand for the development of solar cell, since great amount of electricity energy has to be consumed during the production, which would certainly increase the cost thereof, and further result in great pollution to environment. Hence, it would be of great importance for the development of other types of solar cell, as well as reducing the amount of silicon used in a solar cell. Organic and plastic solar cells have thus been studied. In 1998, Gratzel M. et al., (Bach U et al., Nature, 1998, 395: 583-585) used OMeTAD as the hole transmission material, and a photoelectric conversion efficiency of 0.74% is achieved. Polymeric material is easy to be processed, and part of polymeric material is photoelectric active; based on such findings, polymeric solar cell has been prepared. In 1993, Sariciftci NS et al., (Sariciftci NS et al., Appl. Phys. Lett., 1993, 62: 585-587) prepares a first polymer/C60 based solar cell.

Carbon nanotube is a stack of nano-material formed from a layer of or several layers of graphite sheet curled in a certain helix angle. Theoretical calculation and testing results indicate that, according to their different geometry, the carbon nanotube could be either metallic or semiconducting. By means of theoretical analysis, Satio et al. (Satio R, et al., Mater. Sci. Eng. B, 19: 185-191) shows that about ⅓ of single walled carbon nanotube is metallic, and ⅔ is semiconducting. Research also shows that, the energy gap of the carbon nanotube may vary from 0 to corresponding to that of silicon, which indicates that carbon nanotube would play an important role in the future semiconductor application. If carbon nanotube is used as solar energy absorption and conversion material, it will absorb sunlight with different wavelength. Study shows that, carbon nanotube has very high conductivity, and the current carrying capacity could achieve up to the order of 10⁹A/cm². Ugarte et al. (de Heer W A et al., Science, 1995, 268: 845-847) discovered that, the radial resistance of carbon nanotube is much larger than axial resistance thereof, and this anisotropy of resistance increases with the decrease of temperature. Li et al., (Li S. D., et al., Nano Lett. 2004, 4: 2003-2007) shows that, the axial resistivity of a single walled carbon nanotube filament is just in the order of 1.4×10⁻⁸Ω·cm, indicating that the carbon nanotube possesses excellent conductivity. Dr. Cao A. Y. (Cao A. Y, et al., Sol. Energ. Mat. Sol. C. 2002, 70: 481-486) showed that, carbon nanotube possesses very high absorption capacity to sunlight energy, and its absorbency in the region of visible light and infrared may be even over 98%, which also indicates that, if such a carbon nanotube material is applied to a solar cell, it would have incomparable advantages to the conventional materials. SinghaA. et al., (SinghaA. et al., Nano. Lett. 2003, 3: 383-388) illustrates that the absorption spectrum of single walled carbon nanotube ranges from visible light to infrared region. Liu L. Y. et al., University of Shanghai Communication (Liu L. Y, et al., Sens. Actuator A-Phys, 2004, 116: 394-397) discovered that, multiple-walled carbon nanotube could produce photocurrent in response to an infrared radiation, thus it could be used as an infrared radiation detecting material. Wei J. Q. et al., (Wei J. Q., et al., Small, 2006, 2: 988-993) discovered that, macro-carbon nanotube bundle could produce photocurrent in response to a laser irradiation (the wavelength of which is in the range from far infrared to visible light).

In view of the excellent performances of carbon nanotube in electrics, optics, and etc. as stated above, the carbon nanotube has the possibility to be applied in solar cells. Practically, study of photoelectric conversion based on carbon nanotube has been developed since the year of 2005. The early studies primarily focus on solar cell of carbon nanotube based composite, including the composite of carbon nanotube and polymer used for photoelectric conversion material. Landi B. J. et al., (Landi B. J. et al., Prog. Photovoltaics, 2005, 13: 165-172) mixed single walled carbon nanotube with poly-trioctylthiophene, the resulting open circuit voltage of the solar cell is 0.98 V, and the short circuit current thereof is 0.12 mA/cm². Kymakis E. et al., (Kymakis E. et al., J. Phys. D-Appl. Phys., 2006, 39: 1058-1062) anneals the solar cell obtained from the mixture of single walled carbon nanotube and poly-trioctylthiophene; then keeps the best annealing temperature of 120° C. for 5 minutes, the resulting open circuit voltage of the solar cell is 0.75 V, and the short circuit current thereof is 0.5 mA/cm².

However, the production of solar cells based on these carbon nanotube composites are to mix pulverous carbon nanotube with polymer, the interaction therebetween is relatively weak, and the interface between the carbon nanotubes differs greatly with the carbon nanotube per se, causing large electrical resistance. Furthermore, electron cavities could easily be recombined either. Meantime, the polymer used is liable to be oxidized, rendering low conversion efficiency to the solar cell. Because the conversion efficiency thereof is so low that it would be in great interest to develop novel carbon nanotube solar cells.

Macro carbon nanotube body with excellent performances has been developed in the art, including the preparations of single-walled carbon nanotube filament (ZL 02100684.9; Zhu H. W. et al., Science, 2002, 296: 884-886), double-walled carbon nanotube filament and film (ZL 03143102.X; Wei J. Q. et al., J. Phys. Chem. B, 2004, 108: 8844-8847), aligned carbon nanotube array (Zhang X. F. et al., Chem. Phys. Lett. 2002, 362: 285-290), and large area, ultra-thin carbon nanotube film (CN 200510123986.2 or CN1803594).

### SUMMARY OF THE INVENTION

The object of the present invention is to overcome the following existing drawbacks: low conversion efficiency of solar cell, complicated production and short life time; provides a carbon nanotube film-based solar cell and the preparation thereof, and to utilize the electrical and optical properties of carbon nanotube, so that relative good conversion efficiency and relative long life time could be achieved.

The technical solution of the present invention lies in the following aspects:

The present invention provides a carbon Nanotube film-based solar cell, comprising carbon nanotube film, silicon substrate, and back electrode successively, characterized in that: the carbon nanotube film functions as a photoelectric conversion material and an upper electrode simultaneously.

The present invention further provides a process for preparing the carbon nanotube film-based solar cell, comprising the steps of:

1) Evaporation plating Ti/Pd/Ag or Ti/Au metal film onto one side of the silicon substrate, wherein the Ti/Pd/Ag or Ti/Au metal film functions as the back electrode of the carbon nanotube film-based solar cell; then leading it out by a wire;

2) Purifying the carbon nanotube, and then spreading it out as a film having a thickness of 50-200 nm; thereafter, transferring this film to the other side of the silicon substrate, allowing the carbon nanotube film to contact with the silicon substrate tightly, so that the carbon nanotube film can function as the photoelectric conversion material and also the upper electrode simultaneously; then leading it out by a wire.

The present invention takes carbon nanotube film as the photoelectric conversion material of a solar cell, its production is simple compared with the conventional silicon based solar cell, and the theoretical silicon usage would decrease at least one half, thus, the cost is low. Furthermore, because carbon nanotube may absorb lights ranging from infrared, visible light and even ultraviolet, even though texture surface or anti-reflection film is not provided, strong absorption to sunlight could still be achieved, hence it facilitates enhancing the conversion efficiency of solar cell. Additionally, relative to common carbon nanotube/polymer based solar cell, the carbon nanotube useful in the present invention is in the form of macroscopically continuous film, the bundles constituting the carbon nanotube possess strong bonds therebetween, thus leading to very small interfacial resistance, which would also facilitate the conduction of electrons. In the meantime, since no organic is used, the life time of the solar cell is improved, too. This carbon nanotube film-based solar cell according to the present invention has a conversion efficiency of 5.5%, thus possessing wide range of applications.

### BRIEF DESCRIPTION OF THE DRAWINGS

FIG. 1 is a schematic structural view of carbon nanotube film solar cell, comprising carbon nanotube film as the photoelectric conversion material and also the upper electrode.

FIG. 2 is a Scanning Electron Microscopic picture of carbon nanotube film spreaded on a silicon substrate.

FIG. 3 is a I-V curve of carbon nanotube film solar cell in response to an intensity of 30 mW/cm² irradiation from a solar energy simulator.

### DETAILED DESCRIPTION OF THE INVENTION

The present invention will be further illustrated with reference to the following figures and specific examples.

FIG. 1 is a schematic structural view of carbon nanotube film solar cell according to the present invention, comprising carbon nanotube film as the photoelectric conversion material and also the upper electrode. This carbon nanotube film-based solar cell includes back electrode 3, silicon substrate 2 and carbon nanotube film 1. The carbon nanotube film functions as the photoelectric conversion material, in the meantime, it also functions as the upper electrode. The back electrode described above is prepared according to following processes: onto the side of silicon substrate, Ti/Pd/Ag or Ti/Au metal film is evaporation plated as the back electrode; besides, conventional preparation method may also be adopted to prepare the back electrode. The silicon substrate used could be monocrystalline silicon, polycrystalline silicon or amorphous silicon, preferably monocrystalline silicon, commercially available from the Institute of Microelectronics of Peking University. Carbon nanotube film could be single walled carbon nanotube, double walled carbon nanotube or aligned carbon nanotube film; such as single walled carbon nanotube prepared by chemical vapor deposition (ZL 02100684.9; Zhu H. W. et al., Science, 2002, 296: 884-886), double walled carbon nanotube (ZL 03 1 43102.X; Wei J. Q. et al., 3. Phys. Chem. B, 2004, 108: 8844-8847) or aligned carbon nanotube (Zhang X. F. et al., Chem. Phys. Lett. 2002, 362: 285-290). Purification of the thus prepared carbon nanotube or film may be conducted as follows: oxidizing it in the air, dipping it in hydrogen peroxide solution, so that the non-crystalline carbon and catalyst particles can be removed via hydrochloric acid dipping, thus obtaining relatively pure carbon nanotube, which aggregates with each other; placing the obtained carbon nanotube in deionized water, and further adding ethanol, acetone or the other organic solutions, then the carbon nanotube being spreading on the surface of deionized water as a carbon nanotube film, having a thickness of 50-200 nm (Application No. 200510123986.2, CN1803594). The obtained carbon nanotube film is transferred to the surface of the back electrode on which silicon substrate is not prepared, then it is dried by using infrared lamp or drying oven, so that carbon nanotube film contacts with silicon substrate tightly. Connecting conductive wires to carbon nanotube film and back electrode respectively, and leading them out as upper electrode and back electrode of the cell.

### Example 1

(1) Onto one side of silicon substrate 2, Ti/Pd/Ag metal layers were evaporation uniformly successively, and used as the back electrode 3 of the carbon nanotube film solar cell, which was then led out by a wire;
(2) After purification, the double walled carbon nanotube in the form of aggregation was placed into deionized water, onto which ethanol solution was further added, then the double walled carbon nanotube spread into a film having a thickness of 100 nm;
(3) The spread double walled carbon nanotube film was transferred to the other side of silicon substrate 2 on which back electrode 3 was not prepared;
(4) The double walled carbon nanotube film was dried under infrared lamp, so that the double walled carbon nanotube film contacted with silicon substrate tightly. The double walled carbon nanotube film was taken as the upper electrode of the solar cell, which was then led out by a wire.

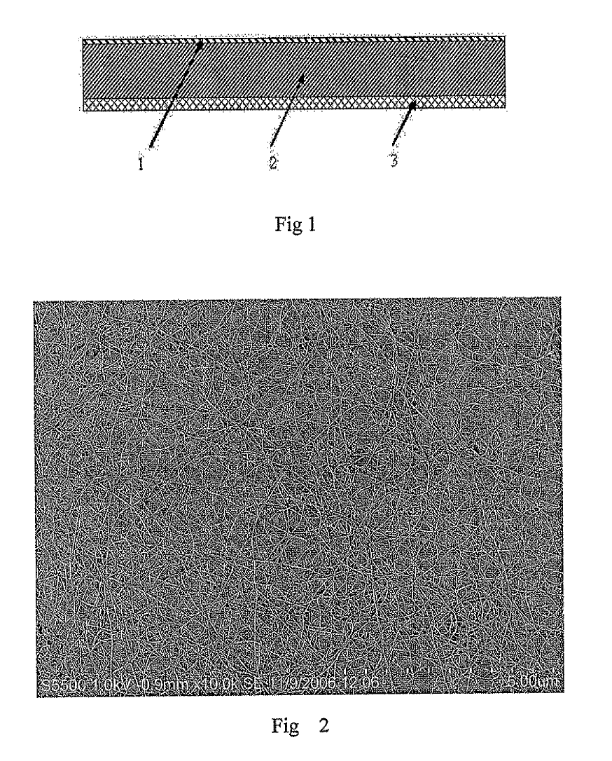

It could be seen from FIG. 2 that the thus prepared carbon nanotube film dispersed evenly on the silicon substrate. Furthermore, it was pure.

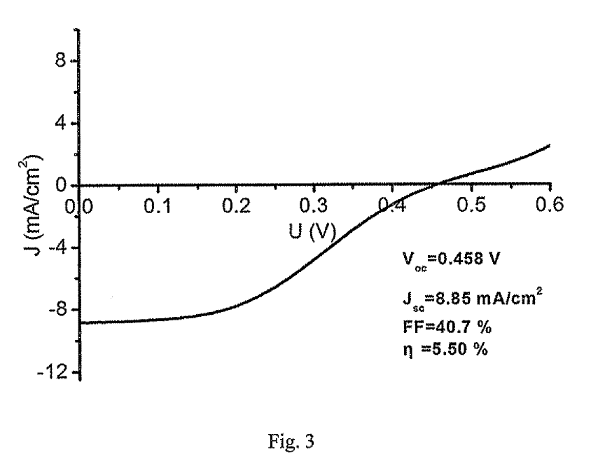

Solar cell conversion efficiency measurement was taken under irradiation of solar energy simulator having an intensity of 30 mW/cm², and the result obtained was shown in FIG. 3. It can be seen from FIG. 3 that the conversion efficiency of solar energy was up to 5.5%.

### Example 2

(1) Onto one side of silicon substrate 2, Ti/Au metal layers were evaporation plated successively, and used as the back electrode 3 of the carbon nanotube film solar cell, It was led out by a wire;
(2) After purification, the single walled carbon nanotube in the form of aggregation was placed into deionized water, onto which acetone solution was further added, then the single walled carbon nanotube spread into a film having a thickness of 50 nm;
(3) The spread single walled carbon nanotube film was transferred to the other surface of silicon substrate 2 on which back electrode 3 was not prepared;
(4) The combined body of the obtained single walled carbon nanotube film obtained in step (3) and silicon substrate in a drying oven, the temperature of which was kept under 50° C. for 3 hours, so that the single walled carbon nanotube film contacted with silicon substrate tightly. The single walled carbon nanotube film was taken as the upper electrode of the solar cell, and then led it out by a wire.

Solar cell conversion efficiency measurement was taken under irradiation of solar energy stimulator having an intensity of 30 mW/cm², the conversion efficiency obtained was 5.4%.

### Example 3

(1) Onto one side of silicon substrate 2, Ti/Pd/Ag metal layers were evaporation plated successively, and used as the back electrode 3 of the carbon nanotube film solar cell. Then it was led out by a wire;
(2) The thus prepared aligned carbon nanotube was ultrasonic treated for 1 hour, so that it was dispersed thoroughly;
(3) The spread single walled carbon nanotube film was transferred to the other surface of silicon substrate 2 on which back electrode 3 was not prepared, obtaining a carbon nanotube film 1 having a thickness of 200 nm;
(4) The carbon nanotube film 1 was dried under infrared lamp, so that the carbon nanotube film 1 contacted with silicon substrate tightly. The carbon nanotube film was taken as the upper electrode of the solar cell. Then led it out by a wire.

Solar cell conversion efficiency measurement was taken under irradiation of solar energy stimulator having an intensity of 30 mW/cm², and the conversion efficiency obtained was 3.5%.

1. A carbon nanotube film-based solar cell, comprising carbon nanotube film (1), silicon substrate (2), and back electrode (3) successively, characterized in that: the carbon nanotube film functions as a photoelectric conversion material and an upper electrode simultaneously.

2. The carbon nanotube film-based solar cell according to claim 1, characterized in that: the carbon nanotube film (1) is a single walled carbon nanotube, a double-walled carbon nanotube or an aligned carbon nanotube film.

3. The carbon nanotube film-based solar cell according to claim 1, characterized in that: the carbon nanotube film has a thickness of 50-200 nm.

4. The carbon nanotube film-based solar cell according to claim 1, characterized in that: the silicon substrate is a monocrystalline silicon substrate.

5. The carbon nanotube film-based solar cell according to claim 1, characterized in that: the back electrode is Ti/Pd/Ag or Ti/Au metal film.

6. A process for manufacturing the carbon nanotube film-based solar cell according to claim 1, characterized in that it comprising the steps of:
1) Evaporation plating Ti/Pd/Ag or Ti/Au metal film onto one side of the silicon substrate, wherein the Ti/Pd/Ag or Ti/Au metal film functions as the back electrode of the carbon nanotube film-based solar cell;
2) Purifying the carbon nanotube and spreading it as a film; transferring this film to the other side of the silicon substrate, allowing the carbon nanotube film to contact with the silicon substrate tightly, so that the carbon nanotube film function as the photoelectric conversion material and also the upper electrode simultaneously.

7. The process for manufacturing the carbon Nanotube film-based solar cell according to claim 6, characterized in that: in the step 2), after the carbon nanotube is transferred to the other side of the silicon substrate, the tight contacting of the carbon nanotube film with the silicon substrate is achieved by drying.

8. The carbon nanotube film-based solar cell according to claim 2, characterized in that: the carbon nanotube film has a thickness of 50-200 nm.

9. The carbon nanotube film-based solar cell according to claim 2, characterized in that: the silicon substrate is a monocrystalline silicon substrate.

10. The carbon nanotube film-based solar cell according to claim 2, characterized in that: the back electrode is Ti/Pd/Ag or Ti/Au metal film.
